(19) United States
(12) Patent Application Publication
(10) Pub. No.: US 2009/0219054 A1
(43) Pub. Date: Sep. 3, 2009

(54) CURRENT MODE LOGIC DIGITAL CIRCUITS

(76) Inventors: Christofer Toumazou, Oxfordshire (GB); Francesco Cannillo, Oxfordshire (GB)

Correspondence Address: PATTERSON & SHERIDAN L.L.P. NJ Office, 3040 Oak Post Road, Suite 1500, Houston, TX, 77056-6582, US

(21) Appl. No.: 12/091,727

(22) PCT Filed: Oct. 27, 2006
(86) PCT No.: PCT/GB2006/050360

§ 371 Date: Oct. 14, 2008

(30) Foreign Application Priority Data
Oct. 27, 2005 (GB) 0521915.9

(51) Int. Cl. H03K 19/094

(52) U.S. Cl. 326/115; 326/119; 326/121

(57) ABSTRACT

A digital circuit comprises: a first arm including a first metal oxide semiconductor field effect transistor (M3) configured to act as a load device; a second arm including a second metal oxide semiconductor field effect transistor (M4) configured to act as a load device; and a switch (M1, M2) for selecting one of the first and second arms. Each of the first and second transistors (M3, M4) has a channel length of 100 nm or below and is biased to operate in the weak inversion regime. In an alternative circuit, each load device (M3, M4) has its bulk connected to its drain and is biased to operate in the weak inversion regime.

The present invention relates to current mode logic digital circuits and in particular, though not necessarily, to MOS current mode logic digital circuits.

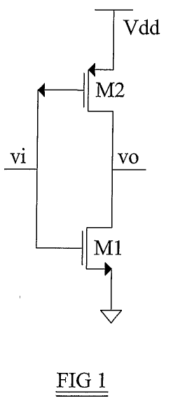

Today, almost all digital circuits are constructed using complementary metal oxide semiconductor (CMOS) field effect transistor (FET) technology. FIG. 1 illustrates schematically a CMOS inverter. When the input voltage vi is “high”, the n-MOSFET (NMOS) M1 is conductive and the p-MOSFET (PMOS) M2 is not conductive, so that the output node is connected to earth via the NMOS M1 and the output voltage is “low”. When the input voltage vi is “low”, the NMOS M1 is not conductive and the PMOS M2 is conductive, so that the output node is connected to the Vdd supply line via the PMOS M2 and the output voltage is “high”.

A fundamental principle underlying the use of CMOS logic is that no current flows through the CMOS transistors when a given circuit is in the quiescent state. Current only flows during switching of the circuit. Power consumption in CMOS logic circuits is therefore extremely low. In practice, even in the quiescent state, leakage currents will flow through the transistors. These leakage currents are relatively small for large scale devices. For example, for transistors using micron level CMOS technologies, the leakage current through a transistor in the quiescent state will be of the order of picoamps.

The operating frequency of a CMOS digital circuit is determined to a large extent by the gate capacitance of a transistor. To enable a circuit to operate at very high frequencies, the gate capacitance, and hence gate size, must be made as small as possible. This means that the channel length must be as short as possible. Current fabrication methods allow channel lengths to be deep in the sub-micron range.

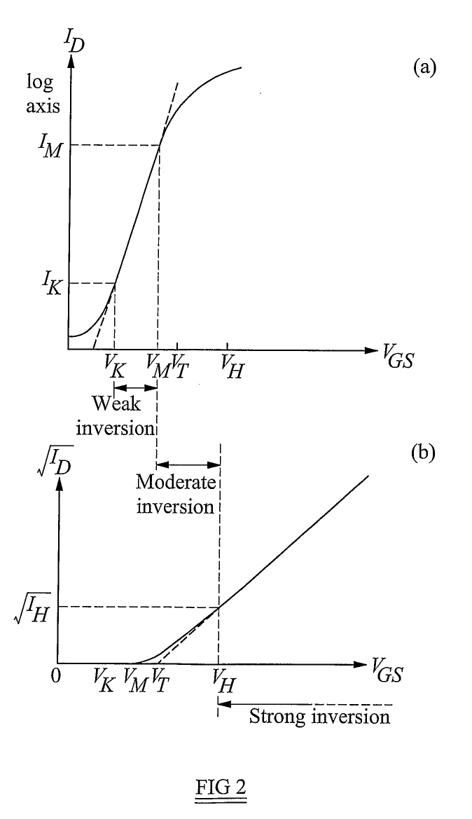

At sub-micron channel lengths, the switching voltage which can be applied to the MOSFET gate must be reduced in order to avoid damaging the device. Typically, for 0.13 μm to 0.18 μm technologies, the switching voltage must be of the order of 1.8V or less. The switching voltage therefore starts to approach the conventional MOSFET threshold voltage, which is the voltage V_{T} shown in FIGS. 2(a) and 2(b). (FIGS. 2(a) and 2(b) are taken from “Operation and Modelling of the MOS Transistor”, Yannis Tsividis, Oxford University Press (2003). Device designs are therefore modified to reduce the threshold voltage. This however results in the need for a negative gate-source [source-gate] voltage in order to completely switch off an NMOS [PMOS] device, hence a higher sub-threshold leakage current exists when an off voltage of close to zero volts is used. CMOS digital circuits therefore start to become power hungry, and in addition begin to suffer from reduced switching noise immunity and supply voltage fluctuation related problems.

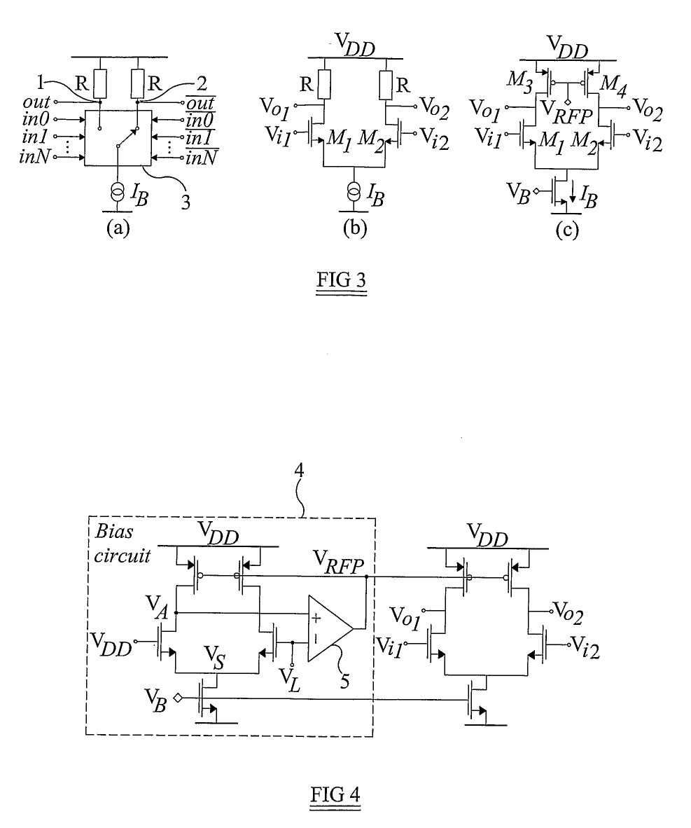

An alternative to CMOS logic is that known as current mode logic (CML). (When implemented using bipolar transistors as opposed to MOSFETs, CML is sometimes known as emitter couple logic (ECL).) CML is based upon the differential pair illustrated schematically in FIG. 3(a) and draws a substantially constant current from the power supply. By applying a suitable voltage swing on the differential input, the constant current can be steered from one branch of the circuit to the other. The impact of leakage currents is of minor importance in CML, since these currents are a part of the constant current source supply. Due to this constant current flow from supply to ground, the switching noise is reduced and since the operation of CML is based on the differential pair, problems due to supply voltage fluctuations are reduced as well.

CML is preferred for mixed analogue-digital signal environments in order to reduce the digital interference between the analogue and the digital blocks. The constant current source used in CML is the reason for constant power consumption, which is independent from the frequency of operation or gate activity. The power consumption is independent of the frequency because the two branches are driven symmetrically and in opposition of phase.

Adaptive pipelining techniques can be applied to sense the required speed of operation and reduce the power dissipation of the CML by changing the voltage swing accordingly, as suggested by M. Mizumo et al. in ‘A GHz MOS Adaptive Pipeline Technique Using MOS Current-Mode Logic’, IEEE Journal of Solid-state Circuits, June 1996, Vol. 31, No. 6, pp. 784-791.

In applications where low-power, low frequencies are required, CML has not been preferred due to its constant static power consumption.

In power-constrained applications, such as medical applications, processing may be performed with CMOS based analogue techniques, where the MOSFET transistors are operated in the weak inversion region, which is also known as the “sub-threshold regime” or the “sub-V_{T} regime”. In weak inversion, the transistor is characterised by the exponential behaviour of the weak inversion drain-source current I_{DS} with respect to the gate-source voltage (V_{GS}) and this behaviour is modelled for an NMOS device by:

$${I}_{DS} = \frac{W}{L} {I}_{M} exp ( \frac{{V}_{GS} - {V}_{M}}{{nU}_{T}} ) [ 1 - exp ( - \frac{{V}_{DS}}{{U}_{T}} ) ] \qquad ( 1 )$$

for V_{GS}≦V_{M}·V_{GS} is the gate-source voltage of the transistor and V_{M} is the value of V_{GS} for which “moderate” inversion begins. This can be seen in the MOSFET current versus voltage plots of FIGS. 2(a) and 2(b) which show, respectively log I_{D}, and √I_{D} against the gate-source voltage V_{GS}. For V_{GS}≧V_{M} the exponential relationship between V_{GS} and I_{DS} ends. For a drain-source voltage (V_{DS}) more than a few U_{T}, (where U_{T} is the thermal voltage, which is approximately 25 mV at room temperature) the transistor is operating in the saturation region. In equation (1) W/L is the width to length ratio of the transistor, and I_{M} and n are process dependent factors (where n is usually between 1-2). The transition frequency, f_{T}, of a MOSFET device operating in weak inversion can reach several hundreds of MHz.

Weak inversion digital circuits can operate up to a few MHz, whilst the power consumption can be very low, e.g. of the order of nano-watts. Any digital processing which is required in these micropower regimes is implemented using weak inversion Static CMOS. Weak inversion Static CMOS however is very sensitive to process, temperature variation, power supply variations (robustness problems), and modifications of the simple static CMOS logic have had to be developed to overcome these problems. In the Variable Threshold weak inversion CMOS technique (see “A 0.9-V, 150-MHz, 10-mW, 4 mm², 2-D discrete cosine transform core processor with variable threshold-voltage (VT) scheme”, T. Kurodaet al., Solid-State Circuits, IEEE Journal of Volume 31, Issue 11, November 1996 pages: 1770-1779), the leakage current is monitored by control circuits and an appropriate bias is applied to the substrate of the transistors to prevent any change in current due to temperature, process, power supply and other variations. However leakage currents are not eliminated and extra circuitry is needed for robustness. Some other circuits use the Pseudo-NMOS sub-threshold logic (see “Ultra-low-power DLMS adaptive filter for hearing aid applications”, C. H.-I Kim et al., Very Large Scale Integration (VLSI) Systems, IEEE Transactions on Volume 11, Issue 6, December 2003 Pages:1058-1067), which is another modification of weak inversion Static CMOS in order to operate the circuits in ultra-low power whilst achieving some improvement in operating speed. However the robustness problems are very comparable to normal weak inversion CMOS logic.

Co-pending UK patent application No. 0415546.1 discloses operations of MOSFETs biased to operate in the weak inversion regime in a CML configuration.

As stated above, the scaling of the channel length (L) in CMOS technology requires a proportionate scaling of the transistor threshold voltage (V_{T}), which, in turn, causes an exponential increase in the weak inversion leakage current. This has been reported by S. Borkar in ‘Design challenges of technology scaling’, IEEE Micro, 1999, Vol. 19(4), pp. 23-29. Therefore, this weak inversion leakage current can no longer be neglected in the power consumption of digital circuits. A design approach to reduce the growing power trend is to minimize the energy spent per logic operation by using MOS devices working in the weak inversion region, i.e. with the lowest operating voltages. To date, most weak inversion processing has been used in the analogue domain to create nano-power circuits. However, weak inversion Static Logic (SL) circuits have also been presented, by H. Soeleman et al. in ‘Robust sub-threshold logic for ultra-low power operation’, IEEE Transactions on Very Large Scale Integration (VLSI) Systems, February 2001, Vol. 9, No. 1, pp. 90-99, for digital processing in mixed signal systems.

To improve the digital operation robustness, Current Mode Logic (CML) architectures are recommended. They, in fact, provide higher immunity to supply noise due to their differential structure, lower cross talk due to the reduced output voltage swing and lower generated noise level due to the constant current flowing through the supply rails. The weak inversion CML approach has been used in the Current Mode Differential Logic (CMDL) reported by M. N. Martin et al. in ‘Current-Mode differential logic circuits for low power digital systems,’ IEEE 39th Midwest symposium on Circuits and Systems, August 1996, Vol. 1, pp. 183-186. The CMDL inverter gate consists of an all-MOS differential pair adopting transistors operating in the weak inversion saturation region.

A first aspect of the present invention provides a digital circuit comprising: a first arm including a first metal oxide semiconductor field effect transistor configured to act as a load device; a second arm including a second metal oxide semiconductor field effect transistor configured to act as a load device; and a switching means for selecting one of the first and second arms; wherein each of the first and second transistors has a channel length of 100 nm or below and is biased to operate in the weak inversion regime.

In the approach of Martin et al. (above), when more gates are cascaded, the input-output dc offset is tolerated by interleaving NMOS-input and PMOS-input differential stages. To guarantee input/output compatibility of the digital gates, the present invention applies, in the weak inversion regime (sub-threshold regime), the MCML approach, which, up to now, has found applications only with transistors operating in strong inversion. By reducing the channel length of the transistors that act as the load devices to 100 nm or below, it is feasible to implement weak inversion MCML with logic swings that guarantee robustness of operation.

A second aspect of the present invention provides a digital circuit comprising: a first arm including a first metal oxide semiconductor field effect transistor configured to act as a load device; a second arm including a second metal oxide semiconductor field effect transistor configured to act as a load device; and a switching means for selecting one of the first and second arms; wherein each load device has its bulk connected to its drain and is biased to operate in the weak inversion regime.

A third aspect of the invention provides an integrated circuit comprising a plurality of digital circuits of the first aspect or second aspect.

A fourth aspect of the invention provides a method of computing a logical function, the method comprising applying an input signal to the gates of the first and second metal oxide semiconductor field effect transistors of a digital circuit of the first or second aspect.

Preferred embodiments of the present invention will now be described by way of illustrative example with reference to the accompanying figures in which:

FIG. 1 illustrates the schematic of a CMOS inverter;

FIGS. 2(a) and 2(b) illustrate the drain current versus gate-source voltage characteristics for an NMOS device;

FIG. 3(a) illustrates the general concept of CML circuits;

FIG. 3(b) illustrates a CML inverter circuit loaded by resistances;

FIG. 3(c) illustrates an all-MOSFET CML inverter circuit;

FIG. 4 shows a bias circuit of the all-MOSFET CML inverter circuit;

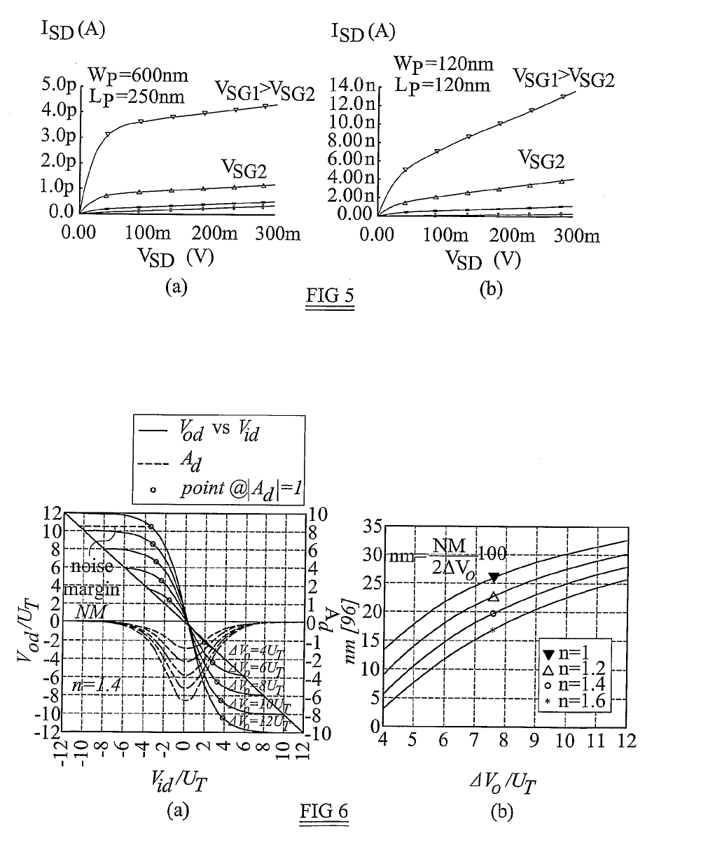

FIGS. 5(a) and 5(b) illustrate weak inversion source-drain current versus source-drain voltage characteristics for a PMOS device;

FIGS. 6(a) and 6(b) illustrate the theoretical input-output differential characteristics and the noise margin, respectively, for a differential pair inverter of FIG. 3(b);

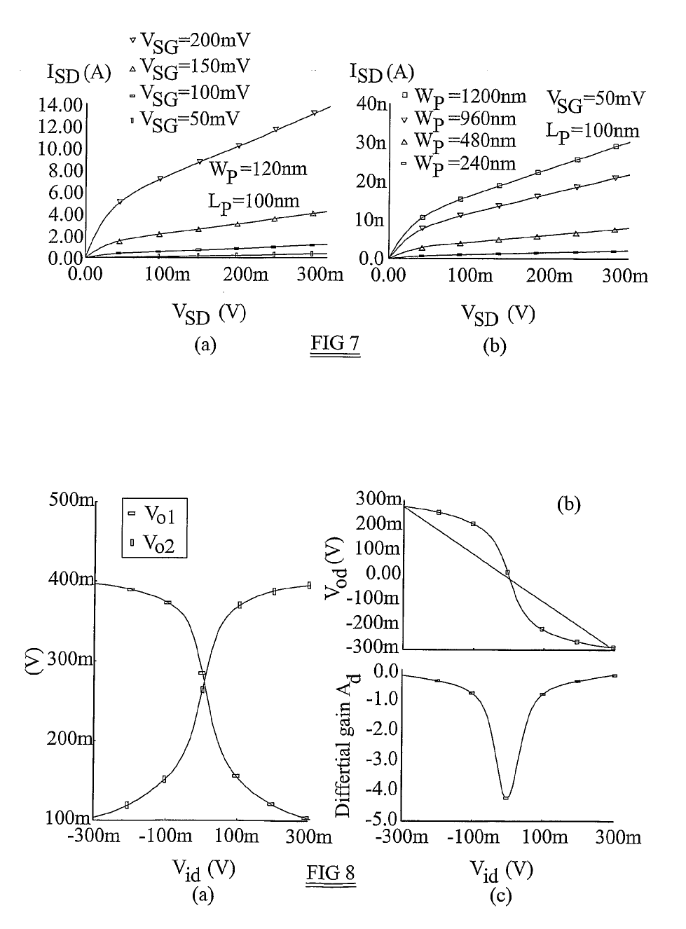

FIGS. 7(a) and 7(b) show simulations of the source-drain current versus source-drain voltage characteristics for a MOSFET with a channel length of 100 nm;

FIGS. 8(a) and 8(b) show the simulated dc input-output characteristics of an inverter of the present invention;

FIG. 8(c) shows the simulated differential gain of an inverter of the present invention;

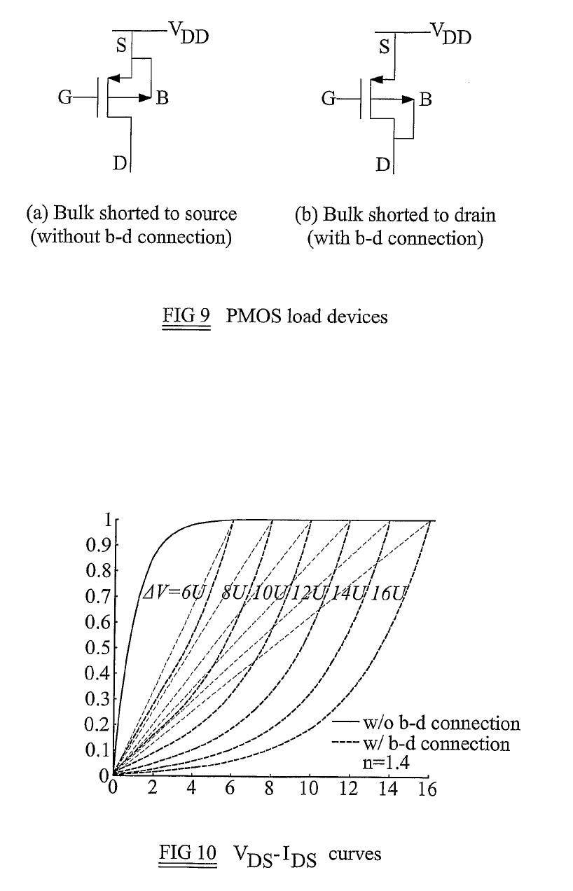

FIG. 9(a) is a schematic circuit diagram of an MOSFET in which the bulk of the MOSFET is shorted to the source;

FIG. 9(b) is a schematic circuit diagram of an MOSFET in which the bulk of the MOSFET is shorted to the drain;

FIG. 10 shows V_{DS}−I_{Ds} curves for MOSFETs in which the bulk is shorted to the drain and for a MOSFET in which the bulk is shorted to the source;

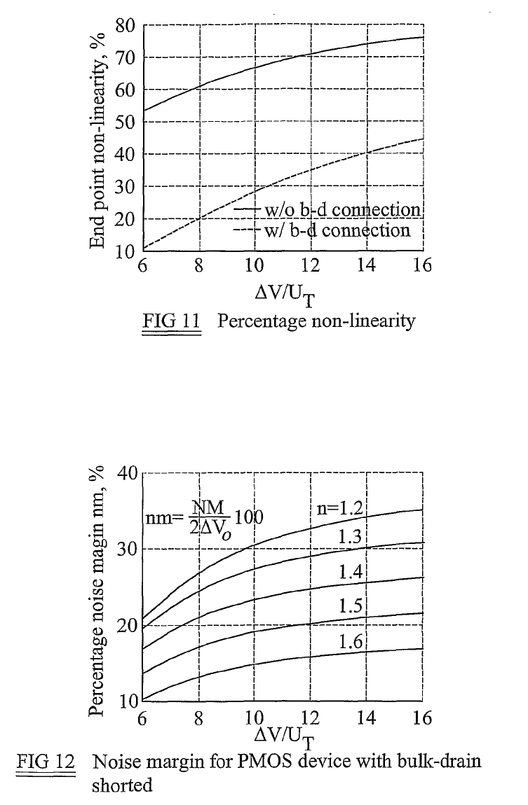

FIG. 11 shows the percentage non-linearity of V_{DS}−I_{DS} curves for MOSFETs in which the bulk is shorted to the drain and for MOSFETs in which the bulk is shorted to the source; and

FIG. 12 shows the noise margin for MOSFETs in which the bulk is shorted to the drain.

The present invention will be described with reference to an inverter gate. However, the invention is not limited to an inverter gate, and can be applied to more complex logic gate topologies.

In order fully to understand the present invention, an understanding of the MCML architecture is required.

In CML logic, resistors are used as loads as shown in FIG. 3(a). FIG. 3(a) is a schematic circuit of a CML digital gate. The value of the pull up device resistance sets the logic swing, ΔVₒ, of the two output nodes 1, 2: ΔVₒ=RI_{B}. ΔVₒ is the maximum voltage variation of the nodes 1 and 2. The sign of the differential output voltage (defined as V_{od}=Vₒ₁−Vₒ₂) is changed if the arm of the inverter through which the current flows is changed by changing the state of switch 3. When processing digital signal, the input and output voltage swings are preferably equal (that is, ΔVᵢ=ΔVₒ) so that the logic “high” and the logic “low” voltages at the output of the circuit are equal to the logic “high” and the logic “low” voltages at the input of the circuit.

As shown in FIG. 3(b), the switch 3 may be implemented by a pair of NMOS transistors M1, M2 arranged as a source-coupled pair that steers I_{B} between the two arms of the inverter.

In MOS common mode logic, or MCML, MOS devices are used as loads. MCML gates are differential and steer the tail current I_{B} between two pull up MOS devices acting as resistances.

In its simplest form, MCML architecture is based on a single MOS type differential pair. FIG. 3(c) shows a practical implementation of an MCML inverter gate. The pull-up resistance in each arm of the circuit of FIG. 3(a) are now implemented by two PMOS load devices M3, M4. The inverter gate again contains a switch for steering I_{B} between the two arms of the circuit, and in FIG. 3(c) the switch comprises two NMOS transistors M1, M2 arranged as a source-coupled pair. The PMOS load devices are biased, and so sized, as to exhibit a constant output resistance R. The PMOS bias voltage, V_{RFP}, is defined by a feedback circuit, which may be shared among several logic gates as suggested by J. M. Musicer et al. in ‘MOS current mode logic for low power, low noise CORDIC computation in mixed-signal environments’, Proceedings of International Symposium on Low Power Electronics and Design, 2000, pp. 102-107. A suitable bias circuit is shown as 4 in FIG. 4. It consists of a replica of the inverter gate and an operational amplifier or opamp (single stage operational transconductance amplifier, OTA) 5. The inputs of the replica inverter in the bias circuit are such that all I_{B}, ideally, flows in one branch. The opamp 5 forces the low output voltage, V_{A}, to be the same as the desired low logic level V_{L}, by changing the gate-source voltage, V_{GS}, and hence the PMOS load resistance.

In the weak inversion regime, the gate-source voltage of the PMOS devices M3, M4 is maintained below the threshold voltage V_{T} shown in FIG. 2 so that the PMOS devices operate in the weak inversion regime (as noted above, this regime is also known as the sub-threshold regime). In the weak inversion regime the linear region of the ideal I_{DS}−V_{DS} (drain-source current, I_{DS}, versus drain-source voltage, V_{DS}) characteristic of a PMOS device is limited to voltages below the weak inversion saturation voltage V_{DSsat}, which is typically 4 or 5 times the thermal voltage U_{T} (which, as noted above, is about 25 mV at room temperature). It thus appears that MCML is implementable in the weak inversion regime only for logic swings below 100 mV—which, however, do not provide enough noise margin for the gate operation.

According to the invention, however, the logic swing of an MCML circuit in the weak inversion regime can be increased by the use of sub-100 nm technologies—that is, by using devices with a channel length of 100 nm or below as the load devices M3,M4. Transistors with a channel length L of 100 nm or below are affected by well-established short-channel secondary effects that contribute to the linearization of the overall behaviour of their weak inversion I_{DS}−V_{DS} characteristics. This has been reported by R. R. Troutmann in ‘VLSI limitations from drain-induced barrier lowering’, IEEE Transactions on Electron Devices, April 1979, Vol. 26, No. 4, pp. 461-469. As a result of these short-channel secondary effects, the difference in slope between the linear region and the saturation region of the I_{DS}−V_{DS} characteristic is reduced due to the finite resistance of the saturation region. In the saturation region, the dependence of I_{DS} on V_{DS} is due to the drain induced barrier lowering (DIBL) effect, reported by Troutmann (above) and, for a PMOS device with V_{BS}=0 (where V_{BS} is the base-source voltage), can be modelled by the BSIM model equation, given by B. J. Sheu et al. in ‘BSIM: Berkeley short-channel IGFET model for MOS transistors’, IEEE J. Solid-State Circuits, August 1987, Vol. 22, No. 4, pp. 558-566, as:

$$\vert {I}_{DS} \vert = A {e}^{\frac{\vert {V}_{GS} \vert}{{nU}_{T}}} {e}^{\frac{η \vert {V}_{DS} \vert}{{nU}_{T}}} ( 1 - {e}^{- \frac{\vert {V}_{DS} \vert}{{U}_{T}}} ) \qquad ( 2 )$$

where η is the DIBL coefficient, n>1 is the weak inversion slope factor and A is given by:

A=μC′ₒₓ(W/L_{eff})U_{T}²e^{1.8} (3)

with μ the carrier mobility, C′ₒₓ the gate oxide capacitance per unit area and W/L_{eff} the width-to-effective length ratio of the device.

FIG. 5 shows the simulated weak inversion I_{DS}−V_{DS} characteristics for a minimum size PMOS transistor in (a) 0.25 μm and (b) 90 nm CMOS technologies, for four different values of the gate-source voltage V_{SG}. The channel length of the PMOS transistor is 250 nm in FIG. 5(a) and 100 nm in FIG. 5(b). Unlike the 0.25 μm technology curves, the curves in FIG. 5(b) for the 90 nm CMOS technology do not present a well defined knee around V_{SDsat} (which is approximately 100 mV at room temperature). Therefore, in the 90 nm technology the PMOS devices can be used as linear loads for a V_{SD} that goes from 0 to voltages that exceed V_{SDsat}.

According to the invention, therefore, the digital circuit of FIG. 3(c) is implemented using, as the load devices M3,M4, devices that have a channel length of 100 nm or below, for example that have a channel length of 100 nm or 90 nm, or even below 90 nm, and that are biased to operate in the weak inversion regime. In the embodiment of FIG. 3(c) the load devices M3,M4 are PMOS devices. Use of PMOS devices with a channel length of 100 nm or below enables voltage swings significantly greater than 100 mV to be obtained. The channel length of the load device M3 is, within the limits of manufacturing tolerances, equal to the channel length of the load device M4.

It is expected that, as the channel length of the load devices M3,M4 is made smaller, the DIBL effect will become more pronounced. The channel length of the load devices can therefore be chosen to allow a desired voltage swing to be obtained.

The NMOS devices M1,M2 forming the switch of the circuit of FIG. 3(c) are biased to operate in the weak inversion regime. They may, if desired, have a channel length of less than 100 nm. However, the channel length of the NMOS devices M1,M2 is not critical, and they may have a channel length of 100 nm or greater. The channel length of the device M1 is, within the limits of manufacturing tolerances, equal to the channel length of the device M2 (the circuit is symmetrical, so that a device in one branch has the same characteristics as the corresponding device in the other branch).

Where the invention is applied to a digital circuit in which the PMOS load devices are biased by a bias circuit that contains a replica of the digital circuit, as shown in FIG. 4, the corresponding PMOS devices of the replica circuit in the bias circuit also have a channel length of 100 nm or below. The PMOS devices in the replica circuit have the same channel length as the PMOS devices M3,M4 in the inverter circuit—the replica circuit in the bias circuit has to have the same characteristics as the inverter circuit.

In the case of more complex digital circuits, the bias circuitry can use just an inverter cell instead of the replica of the complex circuitry.

It is possible to estimate the noise margin for the circuit of FIG. 3(b) by considering the circuit of FIG. 3(a). With the NMOS devices M1,M2 operating in the weak inversion saturation region, the inverter input-output differential characteristic, shown in FIG. 6(a), is given, according to C. Mead in ‘Analog VLSI and Neural Systems’ (Addison Wesley, 1989), by

V_{od}=ΔVₒ tan h(V_{id}/2nU_{T}) (4)

where V_{od}=Vₒ₁−Vₒ₂ and V_{id}=Vᵢ₁−Vᵢ₂ are the differential output and input voltages respectively. FIG. 6(b) shows the percentage noise margin, nm, (relative to the nominal differential logic swing 2ΔVₒ) versus ΔVₒ. These noise margin values are overestimates of the values for the actual circuit of FIG. 3(b). In fact, in this circuit, the NMOS devices have a finite output resistance and do not operate in saturation throughout the entire logic swing. They enter the linear region when most of I_{B} is steered in one branch: the NMOS source voltage V_{S} is set to V_{L} by the bias circuit and the NMOS drain voltage drops because of the load.

An MCML inverter operating in the sub-V_{T} regime has been designed in a commercial 90 nm CMOS technology for ΔVₒ=300 mV (V_{DD}=400 mV). The inverter has the general form shown in FIG. 3(c), but the PMOS devices M3,M4 each have a channel length of 100 nm or less, and for example 100 nm or 90 nm. The PMOS devices are biased to operate in the weak inversion regime. The NMOS devices M1,M2 are also biased to operate in the weak inversion regime.

The inverter of the invention has been simulated with Cadence Spectre 5.0.32 with BSIM3v3 models. The bias circuit defines the I_{DS}−V_{DS} curve on which the PMOS transistor operating point lies, by setting V_{RFP}. The source-gate voltage V_{GS} and the size of the PMOS load devices are such that the curve slope for 0<V_{SD}<ΔVₒ approximates the theoretical value R. FIG. 7(a) shows simulated I_{DS}−V_{DS} characteristics of a minimum size PMOS device with channel length L=100 nm for several V_{GS} values, whilst FIG. 7(b) shows simulated I_{DS}−V_{DS} characteristics of PMOS device with channel length L=100 nm for several channel widths at a given V_{GS} voltage. According to the invention, using I_{B}=20nA and W/L=1 μm/0.1 μm, the slope of the PMOS I_{DS}−V_{DS} curve approximates the value of 15 MΩ.

FIGS. 8(a) and 8(b) show simulated dc input-output characteristics for an MCML inverter according to the invention in which each PMOS device has a channel length of 100 nm or below and is biased to operate in the weak inversion regime. The NMOS devices are also biased to operate in the weak inversion regime. FIG. 8(a) shows the voltages Vₒ₁ and Vₒ₂ at the two output nodes, and FIG. 8(b) shows the differential output voltage V_{od}=Vₒ₁−Vₒ₂. The simulated inverter differential gain, |A_{d}|, is shown in FIG. 8(c) and can be seen to be more than 4. The percentage noise margin, nm, is 20%. The estimated noise margin (FIG. 6(b)) is 28% (in the adopted technology n≈1.4).

The static power consumption of the inverter is 8 nW. This does not include the power consumption of the bias circuit—mainly due to the opamp—which can be shared among several logic gates.

The opamp gain contributes to most of the feedback loop gain, |Aₗₒₒₚ| that makes V_{A} track VL (FIG. 4). The small signal closed loop gain of the bias circuit, A_{bias}, is equal to:

$${A}_{bias} = \frac{Δ {V}_{A}}{Δ {V}_{L}} = \frac{- {A}_{loop}}{1 - ( - {A}_{loop} )} \qquad ( 5 )$$

If |Aₗₒₒₚ|>>1 then A_{bias}≈1 and V_{A}≈V_{L}. It follows that, for 1% error between V_{A} and V_{L}, |Aₗₒₒₚ| has to be larger than 100. Therefore, in the invention, an opamp gain of 40 dB guarantees a tracking error of less than 1 mV. Since the feedback defines a dc value, the opamp can be designed in the weak inversion regime with high gain and a small bandwidth and, hence, with a very low power consumption. In addition, the opamp offset can be compensated by applying an adequate voltage at its negative terminal.

The invention is not limited to the differential inverter circuit of FIG. 3(c), and the invention may be applied to more complex logic gate topologies than the inverter gate of FIG. 3(c). The implementation of more complex digital circuits is still based on the differential approach illustrated in FIG. 3(c), but more complex digital circuits have a different arrangement of switches in the branches of the circuit. The differential inverter circuit of FIG. 3(c) may be modified to provide other logic functions, by replacing the source-coupled pair by another switch or combination of switches that, for any combination of digital input, allows current to flow in only one of the branches—the switch or combination of switches may be considered as forming a logic block, and the logic function of the circuit is determined by the logic of this logic block (in the same way that the logic of the circuit of FIG. 3(a) is determined by the logic block connected between the two loads 1,2 and the current source).

In the circuit of FIG. 3(c) the load devices in the arms of the circuit are implemented by PMOS devices, and the switch for selecting one of the arms is implemented by NMOS devices. The invention is not limited to this, and the circuit may alternatively be implemented using NMOS devices as the load devices and using PMOS devices in the switch. In this case the transistors M3, M4 of FIG. 3(c) would be replaced by NMOS devices with a channel length 100 nm or below, and the transistors M1, M2 of FIG. 3(c) would be replaced by PMOS devices (whose channel length may be either below 100 nm or above 100 nm). The PMOS and NMOS devices would be biased to operate in the weak inversion regime.

A plurality of digital circuits of the invention may be incorporated in an integrated circuit.

A digital circuit of the invention may be used a method of computing a logical function. An output may be obtained by applying an input signal to the gates of the first and second metal oxide semiconductor field effect transistors of a digital circuit of the invention; in the case of the digital circuit of FIG. 3(c), for example, by applying an input signal to the gates of the first and second NMOS devices M1,M2.

In the embodiments described thus far, the PMOS load devices are assumed to have their bulk (or body) connected to the positive supply voltage V_{DD}. Since the load devices also have their sources connected to the voltage supply V_{DD}, each load device has its bulk shorted to its source and the source-bulk voltage V_{SB} is zero. This is the normal means of operating a PMOS transistor, and avoids threshold voltage modulation due to the body effect.

Another embodiment of the invention uses load devices, for example PMOS load devices, in which the bulk of the device is tied to the drain of the device—i.e., with the drain-bulk voltage V_{DB} set to zero. This has been found to extend the linear operating range of the load: that is, to provide an increase in the output voltage swing over which linear load operation is maintained. In this case load devices with channel lengths greater than 100 nm may also be used, while still achieving linear operation of the load.

Equation (1) above may also be expressed as:

$$\begin{matrix}{I}_{DS } = {I}_{o} exp ( \frac{{V}_{GS}}{{nU}_{T}} ) [ 1 - exp ( - \frac{{V}_{DS}}{{U}_{T}} ) ] \\ where & ( 6 ) \\ {I}_{o} - {I}_{s} exp - ( \frac{{V}_{TO} + ( n - 1 ) {V}_{SB}}{{nU}_{T}} ) & ( 7 )\end{matrix}$$

Iₛ (specific current) and V_{TO} (threshold voltage for V_{SB}=0) are both process constants. Re-writing equation (6) with V_{B}=V_{D} (i.e., with the bulk-drain shorted) gives:

$${I}_{DS} = {I}_{s} exp ( \frac{{V}_{GS} - {V}_{TO}}{{nU}_{T}} ) exp ( - \frac{{V}_{DS}}{{nU}_{T}} ) [ exp ( \frac{{V}_{DS}}{{U}_{T}} - 1 ) ] \qquad ( 8 )$$

FIGS. 9(a) and 9(b) are schematic circuit diagrams of two PMOS load devices. The load devices are of equal size to one another, but the load device of FIG. 9(a) has V_{B}=V_{DD} (the load device is bulk-to-source shorted) and the load device of FIG. 9(b) has V_{B}=V_{D} (the load device is bulk-to-drain shorted). FIG. 10 shows curves of the drain-source current I_{DS} versus drain source voltage V_{DS} for the PMOS devices of FIGS. 9(a) and 9(b), where the value of the gate source voltage V_{GS} for each device is chosen such that the two types of load device assume the same drain-source current Iₘₐₓ when V_{DS} equals a given value of voltage swing ΔV. The relation between the two values of V_{GS} for the bulk-to-drain shorted device and the bulk-source shorted device can be found by equating equations (1) and (6). In FIG. 10 the solid line shows the I_{DS}−V_{DS} characteristic of the bulk-source connected load device of FIG. 9(a), the dashed lines show an ideal linear characteristic (straight line) joining the points (0,0) and (ΔV, Iₘₐₓ) for six values of ΔV, while the dotted lines show the I_{DS}−V_{DS} characteristic of the bulk-to-drain connected load device of FIG. 9(b).

Although FIG. 10 shows that the I_{DS}−V_{DS} characteristic of the bulk-to-drain connected load device of FIG. 9(b) is non-linear, it can be seen that the deviation of this characteristic from the ideal straight line is less than for the bulk-to-source connected PMOS load device. This is illustrated in FIG. 11, which plots the end-point non-linearity against voltage swing ΔV for the bulk-to-source connected load device of FIG. 9(a) (solid line) and for the bulk-to-drain connected load device of FIG. 9(b) (broken line). In FIG. 11, the end-point non-linearity is defined as the maximum deviation of the I_{DS}−V_{DS} curve from the ideal straight line. FIGS. 10 and 11 are theoretical curves and are valid for technologies that are not affected by short channel effects. In principle, FIGS. 10 and 11 are valid for all micron, sub-micron and deep-sub-micron technologies (where “deep submicron” covers channel lengths below approximately 0.25 μm).

Using a similar method to that described previously, FIG. 12 shown the noise margin nm of the bulk-to-drain connected load device of FIG. 9(b) against differential logic swing 2ΔV₀ for several values of n. This curve is plotted for a bulk-to-drain connected PMOS device. FIG. 12 is again a theoretical curve valid for technologies that are not affected by short channel effects, and in principle is valid for all micron, sub-micron and deep-sub-micron technologies. The circuit of FIG. 3(c) may alternatively be implemented using load devices M₃, M₄ operating in the weak inversion regime and that have a gate length of over 100 nm, provided that the load devices M₃, M₄ are bulk-to-drain connected—as FIG. 12 shows, provided that the load devices M₃, M₄ are bulk-to-drain connected the load devices may in principle be implemented using any micron, sub-micron or deep-sub-micron technology. The load devices may also be implemented as bulk-to-drain connected devices with a channel length of below 100 nm although, in this case, the characteristics may vary from those shown in FIGS. 10, 11 and 12 since, as stated above, FIGS. 10, 11 and 12 do not take account of short channel effects.

1-11. (canceled)

12. A digital circuit comprising: a first arm including a first metal oxide semiconductor field effect transistor configured to act as a load device; a second arm including a second metal oxide semiconductor field effect transistor configured to act as a load device; and a switching means for selecting one of the first and second arms; wherein each of the first and second transistors has a channel length of 100 nm or below and is biased to operate in the weak inversion regime.

13. A digital circuit as claimed in claim 12 wherein each load device has its bulk connected to its drain.

14. A digital circuit comprising: a first arm including a first metal oxide semiconductor field effect transistor configured to act as a load device; a second arm including a second metal oxide semiconductor field effect transistor configured to act as a load device; and a switching means for selecting one of the first and second arms; wherein each load device has its bulk connected to its drain and is biased to operate in the weak inversion regime.

15. A digital circuit as claimed in claim 14 wherein each of the first and second transistors has a channel length of 100 nm or below.

16. A digital circuit as claimed in claim 12 wherein each of the first and second transistors has a channel length of less than 100 nm.

17. A digital circuit as claimed in claim 14 wherein each of the first and second transistors has a channel length of less than 100 nm.

18. A digital circuit as claimed in claim 12 wherein each of the first and second transistors is a PMOS transistor.

19. A digital circuit as claimed in claim 14 wherein each of the first and second transistors is a PMOS transistor.

20. A digital circuit as claimed in claim 12 wherein each of the first and second transistors is an NMOS transistor.

21. A digital circuit as claimed in claim 14 wherein each of the first and second transistors is an NMOS transistor.

22. A digital circuit as claimed in claim 12 wherein the switch comprises third and fourth metal oxide semiconductor field effect transistors configured in a current mode logic configuration.

23. A digital circuit as claimed in claim 14 wherein the switch comprises third and fourth metal oxide semiconductor field effect transistors configured in a current mode logic configuration.

24. A digital circuit as claimed in claim 22 wherein each of the first and second transistors is a PMOS transistor and each of the third and fourth transistors is an NMOS transistor.

25. A digital circuit as claimed in claim 22 wherein each of the first and second transistors is an NMOS transistor and each of the third and fourth transistors is a PMOS transistor.

26. A digital circuit as claimed in claim 12 and further comprising a bias circuit for biasing the first and second transistors to operate in the weak inversion regime.

27. A digital circuit as claimed in claim 14 and further comprising a bias circuit for biasing the first and second transistors to operate in the weak inversion regime.

28. An integrated circuit comprising a plurality of digital circuits as defined in claim 12.

29. An integrated circuit comprising a plurality of digital circuits as defined in claim 14.

30. A method of computing a logical function, the method comprising applying an input signal to the gates of the first and second metal oxide semiconductor field effect transistors of a digital circuit as defined in claim 12.

31. A method of computing a logical function, the method comprising applying an input signal to the gates of the first and second metal oxide semiconductor field effect transistors of a digital circuit as defined in claim 14.
